(19) United States
(12) Patent Application Publication
(10) Pub. No.: US 2024/0105446 A1
(43) Pub. Date: Mar. 28, 2024

(54) SUBSTRATE PROCESSING METHOD, METHOD OF MANUFACTURING SEMICONDUCTOR DEVICE, NON-TRANSITORY COMPUTER-READABLE RECORDING MEDIUM AND SUBSTRATE PROCESSING APPARATUS

(71) Applicant: Kokusai Electric Corporation, Tokyo (JP)

(72) Inventor: Takaaki NODA, Toyama (JP)

(21) Appl. No.: 18/463,435

(22) Filed: Sep. 8, 2023

(30) Foreign Application Priority Data
Sep. 22, 2022 (JP) 2022-151942

(51) Int. Cl. H01L 21/02; C23C 16/34; C23C 16/44; C23C 16/455; C23C 16/52

(52) U.S. Cl. CPC H01L 21/0228; C23C 16/34; C23C 16/4408; C23C 16/45523; C23C 16/52; C23C 16/4412

(57) ABSTRACT

According to the present disclosure, there is provided a technique capable of forming a film with a desired thickness. According to one aspect thereof, there is provided a substrate processing method including: forming a film by performing: (a) forming a first film by performing a first cycle under a first condition, including: (a-1) forming a first layer by supplying a source gas; and (a-2) modifying the first layer into a second layer by supplying a reactive gas; and (b) forming a second film by performing a second cycle under a second condition, including: (b-1) forming a third layer by supplying the source gas; and (b-2) modifying the third layer into a fourth layer by supplying the reactive gas. The first and second conditions are set such that a thickness of the fourth layer formed in (b-2) is smaller than that of the second layer formed in (a-2).

### CROSS REFERENCE TO RELATED APPLICATIONS

This application claims foreign priority under 35 U.S.C. § 119(a)-(d) to Application No. JP 2022-151942 filed on Sep. 22, 2022, the entire contents of which are hereby incorporated by reference.

### TECHNICAL FIELD

The present disclosure relates to a substrate processing method, a method of manufacturing a semiconductor device, a non-transitory computer-readable recording medium and a substrate processing apparatus.

### BACKGROUND

According to some related arts, as a part of a manufacturing process of a semiconductor device, a process of forming a nitride film on a surface of a substrate may be performed by performing a cycle including a step of supplying a source gas to the substrate and a step of supplying a nitrogen-containing gas to the substrate.

When forming a film such as the nitride film on the substrate, a precision with respect to a desired thickness of the film may be required.

### SUMMARY

According to the present disclosure, there is provided a technique capable of forming a film with a desired thickness on a substrate.

According to an aspect the technique of the present disclosure, there is provided a substrate processing method including: forming a film containing a predetermined element and constituted by a first film and a second film on a substrate by performing: (a) forming the first film containing the predetermined element by performing a first cycle a first predetermined number of times under a first condition, wherein the first cycle includes: (a-1) forming a first layer containing the predetermined element by supplying a source gas containing the predetermined element to the substrate; and (a-2) modifying the first layer into a second layer containing the predetermined element by supplying a reactive gas reacting with the first layer to the substrate; and (b) forming the second film containing the predetermined element by performing a second cycle a second predetermined number of times under a second condition different from the first condition, wherein the second cycle includes: (b-1) forming a third layer containing the predetermined element by supplying the source gas to the substrate; and (b-2) modifying the third layer into a fourth layer containing the predetermined element by supplying the reactive gas to the substrate, wherein the first condition and the second condition are set such that a thickness of the fourth layer formed in (b-2) is set to be smaller than a thickness of the second layer formed in (a-2).

### BRIEF DESCRIPTION OF THE DRAWINGS

FIG. 1 is a diagram schematically illustrating a vertical cross-section of a vertical type process furnace of a substrate processing apparatus according to a first embodiment of the present disclosure.

FIG. 2 is a diagram schematically illustrating a horizontal cross-section, taken along a line A-A shown in FIG. 1, of the vertical type process furnace of the substrate processing apparatus according to the first embodiment of the present disclosure.

FIG. 3 is a block diagram schematically illustrating a configuration of a controller and related components of the substrate processing apparatus according to the first embodiment of the present disclosure.

FIG. 4 is a flow chart schematically illustrating an exemplary flow of a substrate processing according to the first embodiment of the present disclosure.

FIG. 5A is a diagram schematically illustrating a film formed by the substrate processing according to the first embodiment of the present disclosure.

FIGS. 5B and 5C are diagrams schematically illustrating a film formed by a substrate processing according to comparative examples of the first embodiment of the present disclosure.

FIG. 6 is a diagram schematically illustrating a vertical cross-section of a vertical type process furnace of a substrate processing apparatus according to a second embodiment of the present disclosure.

### DETAILED DESCRIPTION

### First Embodiment of Present Disclosure

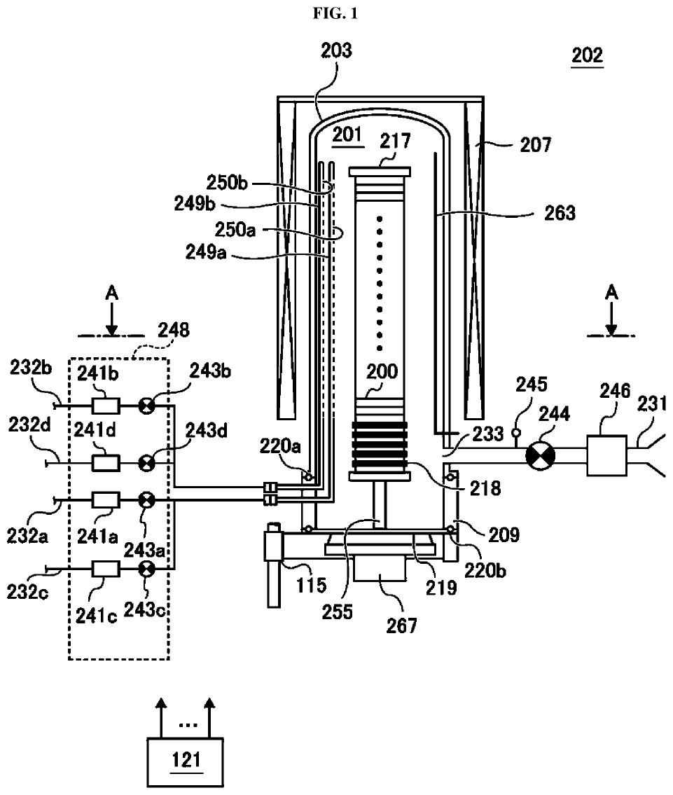

Hereinafter, a first embodiment of the technique of the present disclosure will be described in detail with reference to FIGS. 1 through 5C. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

(1) Configuration of Substrate Processing Apparatus

As shown in FIG. 1, a substrate processing apparatus according to the present embodiment includes a vertical type process furnace (also simply referred to as a “process furnace”) 202. The process furnace 202 includes a heater 207 serving as a heating structure (which is a heating system, a temperature regulator or a temperature adjusting structure). The heater 207 is of a cylindrical shape, and is vertically installed while being supported by a support plate (not shown). The heater 207 also functions as an activator (also referred to as an “exciter”) capable of activating (or exciting) a gas by a heat.

A reaction tube 203 is provided in an inner side of the heater 207 to be aligned in a manner concentric with the heater 207. For example, the reaction tube 203 is made of a heat resistant material such as quartz (SiO2) and silicon carbide (SiC). For example, the reaction tube 203 is of a cylindrical shape with a closed upper end and an open lower end. A manifold 209 is provided under the reaction tube 203 to be aligned in a manner concentric with the reaction tube 203. For example, the manifold 209 is made of a metal material such as stainless steel (SUS). For example, the manifold 209 is of a cylindrical shape with open upper and lower ends. An upper end portion of the manifold 209 is engaged with a lower end portion of the reaction tube 203 so as to support the reaction tube 203. An O-ring 220a serving as a seal is provided between the manifold 209 and the reaction tube 203. Similar to the heater 207, the reaction tube 203 is installed vertically. A process vessel (also referred to as a “reaction vessel”) is constituted mainly by the reaction tube 203 and the manifold 209. A process chamber 201 is provided in a hollow cylindrical portion of the process vessel. The process chamber 201 is configured to be capable of accommodating a plurality of wafers including a wafer 200 serving as a substrate. Hereinafter, the plurality of wafers including the wafer 200 may also be simply referred to as “wafers 200”. The wafer 200 is processed in the process chamber 201.

Nozzles 249a and 249b are provided in the process chamber 201 so as to penetrate a side wall of the manifold 209. Gas supply pipes (pipings) 232a and 232b are connected to the nozzles 249a and 249b, respectively.

Mass flow controllers (also simply referred to as “MFCs”) 241a and 241b serving as flow rate controllers (flow rate control structures) and valves 243a and 243b serving as opening/closing valves are sequentially installed at the gas supply pipes 232a and 232b, respectively, in this order from upstream sides to downstream sides of the gas supply pipes 232a and 232b in a gas flow direction. Gas supply pipes 232c and 232d are connected to the gas supply pipes 232a and 232b, respectively, at a downstream side of the valve 243a and at a downstream side of the valve 243b. MFCs 241c and 241d and valves 243c and 243d are sequentially installed at the gas supply pipes 232c and 232d, respectively, in this order from upstream sides to downstream sides of the gas supply pipes 232c and 232d in the gas flow direction.

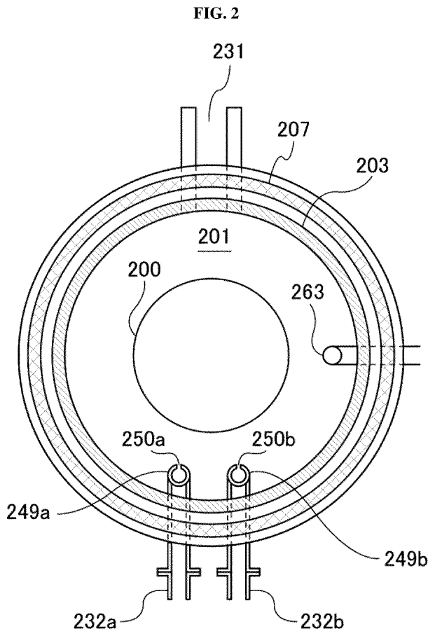

As shown in FIGS. 1 and 2, each of the nozzles 249a and 249b is installed in an annular space provided between an inner wall of the reaction tube 203 and the wafers 200 when viewed from above, and extends upward from a lower portion toward an upper portion of the reaction tube 203 along the inner wall of the reaction tube 203 (that is, extends upward along a stacking direction of the wafers 200). A plurality of gas supply holes 250a and a plurality of gas supply holes 250b are provided at side surfaces of the nozzles 249a and 249b, respectively. The gas supply holes 250a and the gas supply holes 250b are provided from the lower portion toward the upper portion of the reaction tube 203.

A source gas containing a predetermined element is supplied into the process chamber 201 through the gas supply pipe 232a provided with the MFC 241a and the valve 243a and the nozzle 249a.

A reactive gas reacting with the source gas is supplied into the process chamber 201 through the gas supply pipe 232b provided with the MFC 241b and the valve 243b and the nozzle 249b.

An inert gas is supplied into the process chamber 201 through the gas supply pipes 232c and 232d provided with the MFCs 241c and 241d and the valves 243c and 243d, respectively, the gas supply pipes 232a and 232b and the nozzles 249a and 249b. The inert gas supplied through the gas supply pipes 232c and 232d is used as a dilution gas of diluting the source gas when supplied simultaneously with the source gas.

A source gas supplier (which is a source gas supply structure or a source gas supply system) is constituted mainly by the gas supply pipe 232a, the MFC 241a and the valve 243a. A reactive gas supplier (which is a reactive gas supply structure or a reactive gas supply system) is constituted mainly by the gas supply pipe 232b, the MFC 241b and the valve 243b. The source gas supplier and the reactive gas supplier may be collectively or individually referred to as a “gas supplier” which is a gas supply structure or a gas supply system. Further, an inert gas supplier (which is an inert gas supply structure or an inert gas supply system) is constituted mainly by the gas supply pipes 232c and 232d, the MFCs 241c and 241d and the valves 243c and 243d. The gas supplier may further include the inert gas supplier.

Any one or an entirety of the gas suppliers described above may be embodied as an integrated gas supply system 248 in which the components such as the valves 243a through 243d and the MFCs 241a through 241d are integrated. The integrated gas supply system 248 is connected to the respective gas supply pipes 232a through 232d. An operation of the integrated gas supply system 248 to supply various gases to the gas supply pipes 232a through 232d, for example, operations such as an operation of opening and closing each of the valves 243a through 243d and an operation of adjusting flow rates of the gases through each of the MFCs 241a through 241d may be controlled by a controller 121 which will be described later. The integrated gas supply system 248 may be embodied as an integrated structure (integrated unit) of an all-in-one type or a divided type. The integrated gas supply system 248 may be attached to or detached from the components such as the gas supply pipes 232a through 232d on a basis of the integrated structure. Operations such as maintenance, replacement and addition for the integrated gas supply system 248 may be performed on a basis of the integrated structure.

An exhaust pipe 231 through which an inner atmosphere of the process chamber 201 is exhausted is provided at the reaction tube 203. For example, a vacuum pump 246 serving as a vacuum exhaust apparatus is connected to the exhaust pipe 231 through a pressure sensor 245 and an APC (Automatic Pressure Controller) valve 244. The pressure sensor 245 serves as a pressure detector (pressure detection structure) to detect an inner pressure of the process chamber 201, and the APC valve 244 serves as a pressure regulator (pressure adjusting structure). With the vacuum pump 246 in operation, the APC valve 244 may be opened or closed to perform a vacuum exhaust operation of the process chamber 201 or stop the vacuum exhaust operation. With the vacuum pump 246 in operation, the inner pressure of the process chamber 201 may be adjusted by adjusting an opening degree of the APC valve 244 based on pressure information detected by the pressure sensor 245. An exhauster (which is an exhaust structure or an exhaust system) is constituted mainly by the exhaust pipe 231, the APC valve 244 and the pressure sensor 245. The exhauster may further include the vacuum pump 246.

A seal cap 219 serving as a furnace opening lid capable of airtightly sealing (or closing) a lower end opening of the manifold 209 is provided under the manifold 209. For example, the seal cap 219 is made of a metal material such as SUS, and is of a disk shape. An O-ring 220b serving as a seal is provided on an upper surface of the seal cap 219 so as to be in contact with the lower end of the manifold 209. A rotator 267 configured to rotate a boat 217 described later is provided under the seal cap 219. A rotating shaft 255 of the rotator 267 is connected to the boat 217 through the seal cap 219. As the rotator 267 rotates the boat 217, the wafers 200 accommodated in the boat 217 are rotated. The seal cap 219 is elevated or lowered in a vertical direction by a boat elevator 115 serving as an elevating structure provided outside the reaction tube 203. The boat elevator 115 is configured to be capable of transferring (loading) the boat 217 into the process chamber 201 and capable of transferring (unloading) the boat 217 out of the process chamber 201 by elevating and lowering the seal cap 219. The boat elevator 115 serves as a transfer device (which is a transfer structure or a transfer system) capable of transferring the boat 217 (and the wafer 200 accommodated therein) into or out of the process chamber 201.

The boat 217 (which is a substrate support or a substrate retainer) is configured such that the wafers 200 (for example, 25 wafers to 200 wafers) are accommodated (or supported) in the vertical direction in the boat 217 while the wafers 200 are horizontally oriented with their centers aligned with one another with a predetermined interval therebetween in a multistage manner. For example, the boat 217 is made of a heat resistant material such as quartz and SiC. For example, a plurality of heat insulation plates 218 made of a heat resistant material such as quartz and SiC are supported at a lower portion of the boat 217 in a multistage manner.

A temperature sensor 263 serving as a temperature detector is installed in the reaction tube 203. A state of electric conduction to the heater 207 is adjusted based on temperature information detected by the temperature sensor 263 such that a desired temperature distribution of an inner temperature of the process chamber 201 can be obtained. The temperature sensor 263 is L-shaped, and is provided along the inner wall of the reaction tube 203.

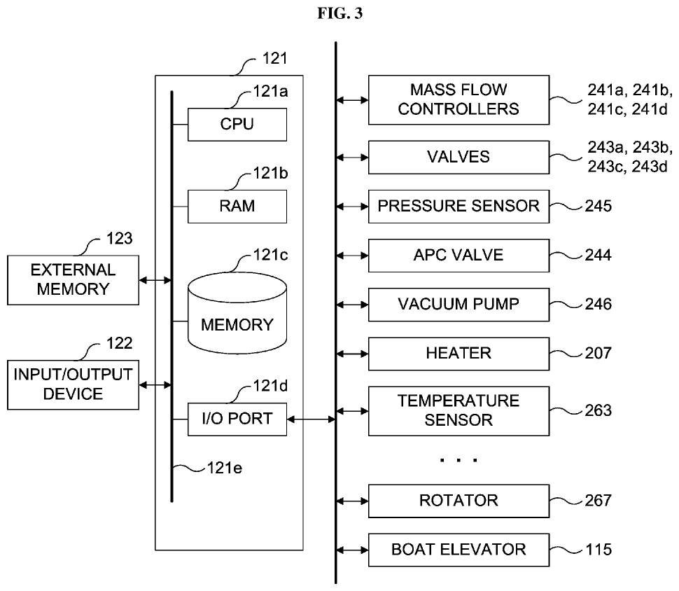

As shown in FIG. 3, the controller 121 serving as a control device (control structure) is constituted by a computer including a CPU (Central Processing Unit) 121a, a RAM (Random Access Memory) 121b, a memory 121c and an I/O port 121d. The RAM 121b, the memory 121c and the I/O port 121d may exchange data with the CPU 121a through an internal bus 121e. For example, an input/output device 122 constituted by a component such as a touch panel is connected to the controller 121.

The memory 121c is configured by a component such as a flash memory, a hard disk drive (HDD) and a solid state drive (SSD). For example, a control program configured to control an operation of the substrate processing apparatus and a process recipe containing information on sequences and conditions of a film-forming process (substrate processing) described later may be readably stored in the memory 121c. The process recipe is obtained by combining steps of the film-forming process described later such that the controller 121 can execute the steps to acquire a predetermined result, and functions as a program. Hereinafter, the process recipe and the control program may be collectively or individually referred to as a “program”. In addition, the process recipe may also be simply referred to as a “recipe”. Thus, in the present specification, the term “program” may refer to the recipe alone, may refer to the control program alone or may refer to both of the recipe and the control program. The RAM 121b functions as a memory area (work area) where a program or data read by the CPU 121a is temporarily stored.

The I/O port 121d is connected to the components described above such as the MFCs 241a through 241d, the valves 243a through 243d, the pressure sensor 245, the APC valve 244, the vacuum pump 246, the heater 207, the temperature sensor 263, the rotator 267 and the boat elevator 115.

The CPU 121a is configured to read the control program from the memory 121c and execute the read control program. In addition, the CPU 121a is configured to read the recipe from the memory 121c, for example, in accordance with an operation command inputted from the input/output device 122. In accordance with the contents of the read recipe, the CPU 121a may be configured to be capable of controlling various operations such as flow rate adjusting operations for various gases by the MFCs 241a through 241d, opening and closing operations of the valves 243a through 243d, an opening and closing operation of the APC valve 244, a pressure regulating operation (pressure adjusting operation) by the APC valve 244 based on the pressure sensor 245, a start and stop operation of the vacuum pump 246, a temperature adjusting operation by the heater 207 based on the temperature sensor 263, an operation of adjusting a rotation and a rotation speed of the boat 217 by the rotator 267 and an elevating and lowering operation of the boat 217 by the boat elevator 115.

The controller 121 may be embodied by installing the above-described program written and stored in an external memory 123 into the computer. For example, the external memory 123 may include a magnetic disk such as a hard disk, an optical disk such as a CD, a magneto-optical disk such as an MO and a semiconductor memory such as a USB memory. The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone or may refer to both of the memory 121c and the external memory 123. Instead of the external memory 123, a communication interface such as the Internet and a dedicated line may be used for providing the program to the computer.

### (2) Substrate Processing

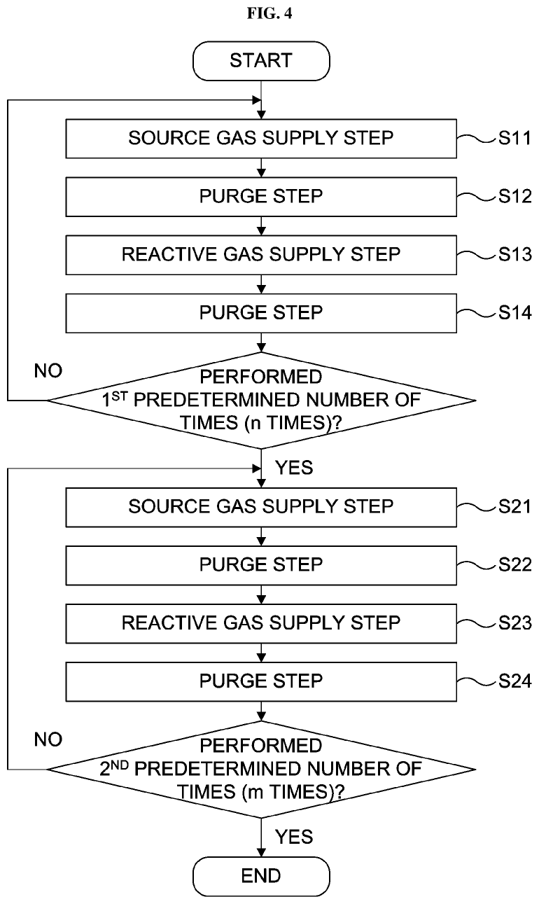

Hereinafter, an exemplary flow (exemplary process sequence) of the substrate processing (film-forming process) of forming a film containing the predetermined element on the substrate (that is, the wafer 200) will be described with reference to FIG. 4. The substrate processing serves as a part of a manufacturing process of a semiconductor device such as an IC (integrated circuit), and is performed by using the substrate processing apparatus described above. In the following descriptions, operations of components constituting the substrate processing apparatus are controlled by the controller 121.

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, “forming a predetermined layer (or a film) on a wafer” may refer to “forming a predetermined layer (or a film) directly on a surface of a wafer itself”, or may refer to “forming a predetermined layer (or a film) on a surface of another layer (or another film) formed on a wafer”. In the present specification, the terms “substrate” and “wafer” may be used as substantially the same meaning.

<Wafer Charging Step and Boat Loading Step>

The wafers 200 are charged (transferred) into the boat 217 (wafer charging step). Thereafter, as shown in FIG. 1, the boat 217 supporting the wafers 200 is elevated by the boat elevator 115 and loaded (transferred) into the process chamber 201 (boat loading step). With the boat 217 loaded, the seal cap 219 airtightly seals the lower end of the manifold 209 via the O-ring 220b.

<Pressure Adjusting Step and Temperature Adjusting Step>

Thereafter, the vacuum pump 246 vacuum-exhausts (decompresses and exhausts) the inner atmosphere of the process chamber 201 (that is, a space in which the wafers 200 are accommodated) such that the inner pressure of the process chamber 201 reaches and is maintained at a desired pressure (vacuum degree) (pressure adjusting step). When the vacuum pump 246 vacuum-exhausts the inner atmosphere of the process chamber 201, the inner pressure of the process chamber 201 is measured by the pressure sensor 245, and the APC valve 244 is feedback-controlled based on the pressure information detected by the pressure sensor 245. The vacuum pump 246 continuously vacuum-exhausts the inner atmosphere of the process chamber 201 until at least a processing of the wafer 200 is completed. In addition, the heater 207 heats the process chamber 201 such that a temperature of the wafer 200 in the process chamber 201 reaches and is maintained at a desired temperature (temperature adjusting step). When the heater 207 heats the process chamber 201, the state of the electric conduction to the heater 207 is feedback-controlled based on the temperature information detected by the temperature sensor 263 such that a desired temperature distribution of the inner temperature of the process chamber 201 can be obtained. The heater 207 continuously heats the wafer 200 in the process chamber 201 until at least the processing of the wafer 200 is completed. In addition, the rotation of the boat 217 (and the wafer 200 accommodated therein) is started by the rotator 267. The rotator 267 continuously rotates the boat 217 (and the wafer 200 accommodated therein) until at least the processing of the wafer 200 is completed.

### <First Film Forming Step: High Speed Film-Forming Process>

First, as a first film forming step, the following steps S11 through S14 are sequentially performed.

### <Step S11 (Source Gas Supply Step)>

In the present step, the source gas is supplied to the wafer 200 in the process chamber 201 under a high speed film-forming condition (which is a first condition), and is exhausted. Specifically, the valve 243a is opened such that the source gas is supplied into the gas supply pipe 232a. Then, the source gas whose flow rate is adjusted by the MFC 241a is supplied into the process chamber 201 through the nozzle 249a, and is exhausted through the exhaust pipe 231. In the present step, simultaneously with a supply of the source gas, the valve 243c is opened such that the inert gas is supplied into the gas supply pipe 232c. Then, the inert gas whose flow rate is adjusted by the MFC 241c is supplied into the process chamber 201 together with the source gas, and is exhausted through the exhaust pipe 231. In the present step, simultaneously with the supply of the source gas, the valve 243d is opened such that the inert gas is supplied into the gas supply pipe 232d so as to prevent the source gas from entering the nozzle 249b and/or to dilute the source gas supplied into the process chamber 201. The inert gas is supplied into the process chamber 201 through the gas supply pipe 232d and the nozzle 249b, and is exhausted through the exhaust pipe 231.

The inert gas supplied through the gas supply pipe 232c is mixed with the source gas in the gas supply pipe 232a to dilute the source gas, and then is supplied to the wafer 200 through the gas supply holes 250a of the nozzle 249a. In addition, the inert gas supplied through the gas supply pipe 232d is supplied to the wafer 200 through the gas supply holes 250b of the nozzle 249b, which are supply ports different from those for supplying the source gas. It is possible to dilute the source gas by the inert gas supplied through the gas supply pipes 232c and 232d, and it is also possible to adjust a supply amount distribution of the source gas on a surface of the wafer 200.

Alternatively, in the present step, the inert gas may be supplied through at least one among the gas supply pipe 232c and the gas supply pipe 232d. Further, the inert gas may be supplied to the wafer 200 through at least one among the gas supply pipe 232c and the gas supply pipe 232d during at least a part of a supply period of the source gas.

For example, process conditions when supplying the source gas in the present step are as follows:
A process temperature: from 400° C. to 750° C., preferably from 500° C. to 650° C.;
A process pressure: from 5 Pa to 4,000 Pa, preferably from 10 Pa to 1,333 Pa;
A supply flow rate of the source gas: from 1 sccm to 2,000 sccm, preferably from 50 sccm to 500 sccm;
A supply flow rate of the inert gas (total flow rate): from 1 sccm to 10,000 sccm, preferably from 100 sccm to 5,000 sccm; and
A process time: from 0.1 second to 240 seconds, preferably 1 second to 120 seconds.

For example, in the present specification, the process temperature refers to the temperature of the wafer 200 or the inner temperature of the process chamber 201, and the process pressure refers to the inner pressure of the process chamber 201. In addition, the process time refers to a time duration of continuously performing a process related thereto. The same also applies to the following description. Further, in the present specification, a notation of a numerical range such as “from 400° C. to 750° C.” means that a lower limit and an upper limit are included in the numerical range. Therefore, for example, a numerical range “from 400° C. to 750° C.” means a range equal to or higher than 400° C. and equal to or less than to 750° C. The same also applies to other numerical ranges described in the present specification.

By supplying the source gas containing the predetermined element to the wafer 200 in accordance with the high speed film-forming condition (that is, the process conditions of the present step as described above), a first layer containing the predetermined element is formed on the wafer 200.

As the source gas, for example, a source gas containing silicon (Si) (that is, a silicon-containing gas) may be used. As the silicon-containing gas, for example, a chlorosilane-based gas such as dichlorosilane (SiH2Cl2) gas, trichlorosilane (SiHCl3) gas, tetrachlorosilane (SiCl4) gas and hexachlorodisilane (Si2Cl6) gas may be used. As the silicon-containing gas, for example, a fluorosilane-based gas such as tetrafluorosilane (SiF4) gas, an inorganic silane-based gas such as disilane (Si2H6) gas and an aminosilane-based gas such as trisdimethylaminosilane (Si[N(CH3)2]3H) gas may be used. As the source gas, for example, one or more of the gases exemplified above as the silicon-containing gas may be used.

As the inert gas, for example, nitrogen (N₂) gas or a rare gas such as argon (Ar) gas, helium (He) gas, neon (Ne) gas and xenon (Xe) gas may be used. As the inert gas, for example, one or more of the gases exemplified above as the inert may be used. The same also applies to the steps described below.

### <Step S12 (Purge Step)>

After the step S11 is completed, a residual gas remaining in the process chamber 201 is removed.

Specifically, after the first layer is formed by the step S11, the valve 243a is closed to stop the supply of the source gas into the process chamber 201. In the present step, with the APC valve 244 open, the vacuum pump 246 vacuum-exhausts the inner atmosphere of the process chamber 201 to remove the residual gas remaining in the process chamber 201 such as the source gas which did not react or which contributed to a formation of the first layer and by-products from the process chamber 201. In the present step, by maintaining the valves 243c and 243d open, the inert gas is continuously supplied into the process chamber 201. The inert gas serves as a purge gas in the present step.

### <Step S13 (Reactive Gas Supply Step)>

After the step S12 is completed, the reactive gas is supplied to the wafer 200 in the process chamber 201. Specifically, with the valve 243a closed, the valve 243b is opened such that the reactive gas is supplied into the gas supply pipe 232b. In the present step, the opening and the closing of the valves 243c and 243d can be controlled in similar manners as those of the valves 243c and 243d in the step S11. Then, the reactive gas whose flow rate is adjusted by the MFC 241b is supplied into the process chamber 201 through the nozzle 249b, and is exhausted through the exhaust pipe 231. Thereby, the reactive gas is supplied to the wafer 200. In the present step, the inert gas whose flow rate is adjusted by the MFC 241d is supplied into the process chamber 201 together with the reactive gas, and is exhausted through the exhaust pipe 231. In the present step, the valve 243c is opened such that the inert gas is supplied into the gas supply pipe 232c so as to prevent the reactive gas from entering the nozzle 249a and/or to dilute the reactive gas supplied into the process chamber 201. The inert gas is supplied into the process chamber 201 through the gas supply pipe 232c and the nozzle 249a, and is exhausted through the exhaust pipe 231.

For example, process conditions when supplying the reactive gas in the present step are as follows:
A supply flow rate of the reactive gas: from 100 sccm to 30,000 sccm, preferably from 500 sccm to 10,000 sccm;
A supply flow rate of the inert gas (total flow rate): from 1 sccm to 10,000 sccm, preferably from 100 sccm to 5,000 sccm; and
A process time: from 1 second to 240 seconds, preferably 1 second to 120 seconds.

The other process conditions of the present step are set to be substantially the same as those of the step S11.

By supplying the reactive gas reacting with the first layer to the wafer 200 on which the first layer is formed, the reactive gas reacts with at least a part of the first layer. As a result, the first layer is modified into a second layer 400b containing the predetermined element.

As the reactive gas, for example, a gas containing nitrogen (N) (that is, a nitrogen-containing gas) may be used. In the present step, the nitrogen-containing gas serves as a nitriding gas. By supplying the nitrogen-containing gas, the first layer is modified into a nitride layer, that is, the second layer 400b containing the predetermined element. As the nitrogen-containing gas, for example, a hydrogen nitride-based gas such as ammonia (NH3) gas, diazene (N2H2) gas, hydrazine (N₂H₄) gas and N3H8 gas may be used. As the reactive gas, for example, one or more of the gases exemplified above as the nitrogen-containing gas may be used.

### <Step S14 (Purge Step)>

After the step S13 is completed, a residual gas remaining in the process chamber 201 is removed. Specifically, after the second layer 400b is formed, the valve 243b is closed to stop a supply of the reactive gas into the process chamber 201. In the present step, with the APC valve 244 open, the vacuum pump 246 vacuum-exhausts the inner atmosphere of the process chamber 201 to remove the residual gas remaining in the process chamber 201 such as the reactive gas which did not react or which contributed to a formation of the second layer 400b and by-products from the process chamber 201. In the present step, by maintaining the valves 243c and 243d open, the inert gas is continuously supplied into the process chamber 201. The inert gas serves as the purge gas in the present step.

### <Performing Predetermined Number of Times>

By performing a first cycle including the steps S11 through S14 described above a first predetermined number of times (n times, wherein n is an integer equal to or greater than 1), it is possible to form a first film 400 containing the predetermined element on the wafer 200. As the first film 400, for example, a silicon nitride film (also referred to as a “SiN film”) can be formed.

### <Second Film Forming Step: Low Speed Film-Forming Process>

First, as a second film forming step, the following steps S21 through S24 are sequentially performed under the same process temperature as those of the steps S11 through S14 described above.

In the present embodiment, the same process temperature may refer to substantially the same process temperature. For example, fluctuations and variations in the process temperature that may occur when the heater 207 is controlled so as to maintain the same process temperature can be included within a range of “substantially the same process temperature”. Further, the process temperature in the present specification may refer to the temperature of the wafer 200 or the inner temperature of the process chamber 201. The same also applies to the following description.

### <Step S21 (Source Gas Supply Step)>

In the present step, the source gas (which is the same as the source gas in the step S11 described above) is supplied to the wafer 200 in the process chamber 201 under a low speed film-forming condition (which is a second condition), and is exhausted.

Specifically, similarly to the step S11 described above, the valve 243a is opened such that the source gas is supplied into the gas supply pipe 232a. Then, the source gas whose flow rate is adjusted by the MFC 241a is supplied into the process chamber 201 through the nozzle 249a, and is exhausted through the exhaust pipe 231. In the present step, simultaneously with the supply of the source gas, the valve 243c is opened such that the inert gas is supplied into the gas supply pipe 232c. Then, the inert gas whose flow rate is adjusted by the MFC 241c is supplied into the process chamber 201 together with the source gas, and is exhausted through the exhaust pipe 231. In the present step, simultaneously with the supply of the source gas, the valve 243d is opened such that the inert gas is supplied into the gas supply pipe 232d so as to prevent the source gas from entering the nozzle 249a and/or to dilute the source gas supplied into the process chamber 201. The inert gas is supplied into the process chamber 201 through the gas supply pipe 232d and the nozzle 249b, and is exhausted through the exhaust pipe 231.

The inert gas supplied through the gas supply pipe 232c is mixed with the source gas in the gas supply pipe 232a to dilute the source gas, and then is supplied to the wafer 200 through the gas supply holes 250a of the nozzle 249a. In addition, the inert gas supplied through the gas supply pipe 232d is supplied to the wafer 200 through the gas supply holes 250b of the nozzle 249b, which are supply ports different from those for supplying the source gas. It is possible to dilute the source gas by the inert gas supplied through the gas supply pipes 232c and 232d, and it is also possible to adjust the supply amount distribution of the source gas on the surface of the wafer 200.

Alternatively, in the present step, the inert gas may be supplied through at least one among the gas supply pipe 232c and the gas supply pipe 232d. Further, the inert gas may be supplied to the wafer 200 through at least one among the gas supply pipe 232c and the gas supply pipe 232d during at least a part of a supply period of the source gas.

For example, process conditions when supplying the source gas in the present step are as follows:
A supply flow rate of the source gas: from 1 sccm to 1,000 sccm, preferably from 25 sccm to 250 sccm;
A supply flow rate of the inert gas (total flow rate): from 1 sccm to 20,000 sccm, preferably from 200 sccm to 10,000 sccm; and
A process time: from 0.1 second to 120 seconds, preferably 1 second to 60 seconds. The other process conditions of the present step are set to be substantially the same as those of the step S11.

By supplying the source gas in accordance with the low speed film-forming condition (that is, the process conditions of the present step as described above) to the wafer 200 with the first film 400 formed on the surface thereof, a third layer containing the predetermined element (which is the same as the predetermined element contained in the first film 400) is formed on the first film 400.

In the present step, the low speed film-forming condition refers to a condition under which a thickness of the third layer formed in the present step is set to be smaller (thinner) than a thickness of the first layer formed in the step S11 described above under the high speed film-forming condition. In addition, the low speed film-forming condition may also refer to a condition under which a thickness of a fourth layer 500b formed in the step S23 described later is set to be smaller than a thickness of the second layer 400b formed in the step S13 described above under the high speed film-forming condition. In other words, the low speed film-forming condition may also refer to a condition in which a cycle rate is set to be lower than that in the high speed film-forming condition described above. The cycle rate may refer to a thickness of the film (or a layer) formed per cycle.

Specifically, the supply flow rate of the source gas in the present step is set to be smaller than the supply flow rate of the source gas in the step S11 described above. For example, the supply flow rate of the source gas in the present step is set to about 50% of the supply flow rate of the source gas in the step S11 described above.

For example, a supply time of the source gas per cycle in the present step may be set to be shorter than the supply time of the source gas per cycle in the step S11 described above. For example, the supply time of the source gas per cycle in the present step is set to about half the supply time of the source gas per cycle in the step S11 described above.

For example, a supply concentration of the source gas in the present step may be set to be lower than the supply concentration of the source gas in the step S11 described above. For example, the supply flow rate of the inert gas in the present step is set to be greater than the supply flow rate of the inert gas in the step S11 described above. Thereby, a dilution amount of the source gas in the present step is set to be greater than that when the source gas is supplied in the step S11. As a result, the supply concentration of the source gas is set to be reduced (lowered). For example, the supply flow rate of the inert gas in the present step is set to be twice the supply flow rate of the inert gas in the step S11 described above. Further, a ratio of the supply flow rate of the inert gas to the supply flow rate of the source gas in the present step is set to be greater than the ratio of the supply flow rate of the inert gas to the supply flow rate of the source gas in the step S11 described above. As a result, the supply concentration of the source gas is set to be reduced (lowered). For example, the ratio of the supply flow rate of the inert gas to the supply flow rate of the source gas in the present step is set to about twice the ratio of the supply flow rate of the inert gas to the supply flow rate of the source gas in the step S11 described above. In such a case, it is preferable that a total flow rate of the source gas and the inert gas supplied to the wafer 200 in the step S11 is set to be the same as the total flow rate of the source gas and the inert gas supplied to the wafer 200 in the step S21. By setting the total flow rate of the source gas and the inert gas in the step S21 the same as that in the step S11, it is possible to adjust an exposure amount of the source gas to the wafer 200 without changing the conditions such as the inner pressure of the process chamber 201. Similarly, a partial pressure of the source gas in the space in which the wafers 200 are accommodated in the present step (for example, the partial pressure of the source gas in the process chamber 201) may be set to be lower than the partial pressure of the source gas in the step S11 described above.

That is, by controlling at least one among the supply flow rate of the source gas, the supply time of the source gas and the supply flow rate of the inert gas in the step S11 and this step described above, it is possible to adjust the exposure amount of the source gas. As a result, it is possible to set the thickness of the third layer formed in the present step to be smaller than the thickness of the first layer formed in the step S11 described above. That is, it is possible to set the cycle rate in the present step to be smaller than the cycle rate in the step S11 described above.

In addition, in the present step, by adjusting at least one among a supply amount (supply flow rate) of the source gas, the supply time of the source gas and the supply concentration (partial pressure) of the source gas under substantially the same process temperature as the process temperature in the step S11 described above, it is possible to control the cycle rate while minimizing a change in quality of the film or without changing the quality of the film.

That is, the low speed film-forming condition in the present step and the high speed film-forming condition in the step S11 described above are set so as to adjust the thickness of the layer (that is, the third layer and the first layer) containing the predetermined element formed by supplying the source gas.

### <Step S22 (Purge Step)>

After the step S21 is completed, a residual gas remaining in the process chamber 201 is removed. Specifically, after the third layer is formed, the valve 243a is closed to stop the supply of the source gas into the process chamber 201. In the present step, with the APC valve 244 open, the vacuum pump 246 vacuum-exhausts the inner atmosphere of the process chamber 201 to remove the residual gas remaining in the process chamber 201 such as the source gas which did not react or which contributed to a formation of the third layer and by-products from the process chamber 201. In the present step, by maintaining the valves 243c and 243d open, the inert gas is continuously supplied into the process chamber 201. The inert gas serves as the purge gas in the present step.

### <Step S23 (Reactive Gas Supply Step)>

After the step S22 is completed, the reactive gas (which is the same as the reactive gas in the step S13 described above) is supplied to the wafer 200 in the process chamber 201 under substantially the same conditions and procedures as in the step S13. Specifically, with the valve 243a closed, the valve 243b is opened such that the reactive gas is supplied into the gas supply pipe 232b. In the present step, the opening and the closing of the valves 243c and 243d can be controlled in substantially the same manners as those of the valves 243c and 243d in the step S13. Then, the reactive gas whose flow rate is adjusted by the MFC 241b is supplied into the process chamber 201 through the nozzle 249b, and is exhausted through the exhaust pipe 231. Thereby, the reactive gas is supplied to the wafer 200. In the present step, the inert gas whose flow rate is adjusted by the MFC 241d is supplied into the process chamber 201 together with the reactive gas, and is exhausted through the exhaust pipe 231.

By supplying the reactive gas to the wafer 200 on which the third layer is formed, at least a part of the third layer is modified into a fourth layer 500b containing the predetermined element. For example, by using the nitrogen-containing gas as the reactive gas, the third layer is modified (nitrided) into a nitride layer containing the predetermined element, that is, a fourth layer 500b.

### <Step S24 (Purge Step)>

After the step S23 is completed, a residual gas remaining in the process chamber 201 is removed. Specifically, after the fourth layer 500b is formed, the valve 243b is closed to stop the supply of the reactive gas into the process chamber 201. In the present step, with the APC valve 244 open, the vacuum pump 246 vacuum-exhausts the inner atmosphere of the process chamber 201 to remove the residual gas remaining in the process chamber 201 such as the reactive gas which did not react or which contributed to a formation of the fourth layer 500b and by-products from the process chamber 201. In the present step, by maintaining the valves 243c and 243d open, the inert gas is continuously supplied into the process chamber 201. The inert gas serves as the purge gas in the present step.

### <Performing Predetermined Number of Times>

By performing a second cycle including the steps S21 through S24 described above a second predetermined number of times (m times, wherein m is an integer equal to or greater than 1), it is possible to form a second film 500 containing the predetermined element on the first film 400 of the wafer 200.

That is, by performing a first cycle including the steps S11 through S14 described above the first predetermined number of times and a second cycle including the steps S21 through S24 described above the second predetermined number of times, it is possible to form a third film constituted by the first film 400 and the second film 500 and containing the predetermined element contained in the first film 400 and the second film 500. The first film 400 and the second film 500 contain the same predetermined element, and a composition of the first film 400 is set to be equal to a composition of the second film 500. For example, when the SiN film is formed as the first film 400, the third film constituted by the first film 400 and the second film 500 is also the SiN film. In the present embodiment, the “same” may refer to “substantially the same”. By laminating (stacking) the first film 400 and the second film 500 whose composition is substantially the same as that of the first film 400, it is possible to control a thickness of the third film without substantially changing the composition of the third film.

Further, by setting the process temperature in the step S21 described above at substantially the same process temperature as the process temperature in the step S11 described above, it is possible to suppress a change in the quality of the first film 400 and the quality of the second film 500.

### <After-Purge Step and Returning to Atmospheric Pressure Step>

The inert gas is supplied into the process chamber 201 through each of the gas supply pipes 232c and 232d, and then is exhausted through the exhaust pipe 231. The inert gas serves as the purge gas. Thereby, the inner atmosphere of the process chamber 201 is purged with the purge gas. As a result, a residual gas and reaction by-products remaining in the process chamber 201 are removed from the process chamber 201 (after-purge step). Thereafter, the inner atmosphere of the process chamber 201 is replaced with the inert gas (substitution by inert gas), and the inner pressure of the process chamber 201 is returned to the normal pressure (atmospheric pressure) (returning to atmospheric pressure step).

### <Boat Unloading Step and Wafer Discharging Step>

Thereafter, the seal cap 219 is lowered by the boat elevator 115 and the lower end of the manifold 209 is opened. Then, the boat 217 with the processed wafers 200 supported therein is unloaded (transferred) out of the reaction tube 203 through the lower end of the manifold 209 (boat unloading step). Then, the processed wafers 200 are discharged (transferred) from the boat 217 (wafer discharging step).

For example, when the silicon-containing gas is used as the source gas and the nitrogen-containing gas is used as the reactive gas to form the SiN film, a film-forming sequence of forming the SiN film (that is, the third film described above) may be illustrated as follows.

(Si-containing Gas→N-containing Gas)×n→(Si-containing Gas→N-containing Gas)×m=>SiN

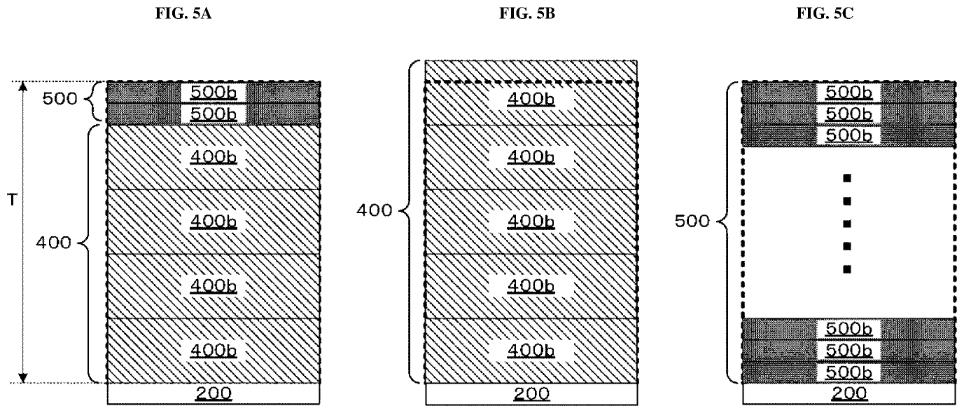

FIG. 5B is a diagram schematically illustrating a case where the film 400 alone is formed on the wafer 200 by repeatedly performing the first cycle including the steps S11 through S14 only under the high speed film-forming condition described above a predetermined number of times. When the film 400 is formed only under the high speed film-forming condition, the cycle rate is high and the thickness of the second layer 400b formed per cycle is large. As a result, it is possible to form the film 400 whose thickness is close to a target thickness T during a small number of executions of the first cycle. Therefore, it is possible to improve a throughput by shortening a film-forming time. On the other hand, the thickness of the film 400 formed only under the high speed film-forming condition can be set to a value obtained by multiplying the thickness of the second layer 400b by a value p (wherein p is an integer equal to or greater than 1). Therefore, when the target thickness T is different from the value obtained by multiplying the thickness of the second layer 400b by the value p, it is not possible to form the film 400 whose thickness is substantially the same as the target thickness T.

FIG. 5C is a diagram schematically illustrating a case where the film 500 is formed on the wafer 200 by repeatedly performing the second cycle including the steps S21 through S24 only under the low speed film-forming condition described above a predetermined number of times. When the film 500 is formed only under the low speed film-forming condition, the cycle rate is low and the thickness of the fourth layer 500b formed per cycle is small as compared with those of the high speed film-forming condition. As a result, in order to form the film 500 whose thickness is substantially the same as the target thickness T, a large number of executions of the second cycle should be performed as compared with a case where the small number of executions of the first cycle is performed under the high speed film-forming condition to form the film 400 whose thickness is close to the target thickness T. In other words, the throughput is lowered because the film-forming time is increased as compared with a case where the high speed film-forming condition is used. On the other hand, it is possible to set an error from the target thickness T to be smaller than that in a case where the high speed film-forming condition is used.

According to the present embodiment, as shown in FIG. 5A, the first film 400 is formed by performing the first cycle including the steps S11 through S14 under the high speed film-forming condition the first predetermined number of times, and the second film 500 is formed by performing the second cycle including the steps S21 through S24 under the low speed film-forming condition the second predetermined number of times. That is, the first predetermined number of times and the second predetermined number of times are adjusted to form the third film constituted by the first film 400 and the second film 500. In other words, two processes with different cycle rates are performed. As a result, it is possible to form the third film containing the predetermined element on the wafer 200 such that the error from the target thickness T can be minimized. In addition, it is possible to shorten the film-forming time and to improve the throughput as compared with a case where only the low speed film-forming condition is applied to form the film 500.

That is, the two processes with different cycle rates are performed to form the third film containing the predetermined element. Specifically, for example, in order to finely adjust the thickness of the third film, for up to about 95% of the target thickness T (which is a desired thickness of the third film), the first film 400 is formed under the high speed film-forming condition with a high cycle rate, and for the remaining about 5% of the target thickness T, the second film 500 is formed under the low speed film-forming condition with a low cycle rate. As a result, it is possible to form the third film with the target thickness T constituted by the first film 400 and the second film 500 and containing the predetermined element on the wafer 200. Therefore, even when a high precision with respect to a desired thickness of the third film is required, it is possible to form the third film with the high precision while improving the throughput.

According to the present embodiment, for example, the first predetermined number of times and the second predetermined number of times are preferably set (selected) such that the error between a total thickness of the first film 400 and the second film 500 and the target thickness T is small, in particular, such that the error is minimized.

For example, the thickness of the second film 500 formed by performing the second cycle including the steps S21 through S24 the second predetermined number of times is set to be smaller than the thickness of the first film 400 formed by performing the first cycle including the steps S11 through S14 the first predetermined number of times. That is, the first predetermined number of times is set to be greater than the second predetermined number of times. For example, the first predetermined number of times is set to be twice or more. By forming the third film with the target thickness T by thickening the thickness of the first film 400 formed under the high speed film-forming condition where the cycle rate is high and adjusting the thickness of the second film 500 formed under the low speed film-forming condition where the cycle rate is low, it is possible to improve the throughput. In addition, by setting the first predetermined number of times of the first cycle performed under the high speed film-forming condition where the cycle rate is high to be greater (thicker) than the second predetermined number of times of the second cycle performed under the low speed film-forming condition where the cycle rate is low, it is also possible to improve the throughput.

Specifically, for example, the first predetermined number of times and the second predetermined number of times are set such that a difference between the target thickness T and the total thickness of the first film 400 and the second film 500 is set to be smaller than a minimum difference between the target thickness T and a thickness obtained by multiplying the thickness of the second layer 400b formed in the step S13 by a value N (wherein N is an arbitrary natural number). As a result, it is possible to reduce the error with respect to the target thickness T.

For example, the first predetermined number of times and the second predetermined number of times may be set such that the thickness of the second film 500 formed under the low speed film-forming condition is set to be smaller than the thickness of the second layer 400b formed per cycle under the high speed film-forming condition. As a result, it is possible to reduce the error with respect to the target thickness T. Further, it is possible to improve the throughput by minimizing the second predetermined number of times.

For example, when the first cycle including the steps S11 through S14 is performed the first predetermined number of times under the high speed film-forming condition such that a remaining thickness, which is a difference between a current thickness and the target thickness T, becomes smaller than the thickness of the second layer 400b formed per cycle, a low speed film-forming process (that is, the second film forming step described above) may be performed. In such a case, the first predetermined number of times (that is, n times, wherein n is an integer equal to or greater than 1) of performing the first cycle including the steps S11 through S14 under the high speed film-forming condition is set such that the value n is maximized while satisfying a condition that a thickness obtained by multiplying the thickness of the second layer 400b formed per each cycle under the high speed film-forming condition by the value n is equal to or less than the target thickness T. After the first film 400 is formed, by finely adjusting the thickness of the second film 500 formed under the low speed film-forming condition by the low speed film-forming process, it is possible to form the film such that the error from the target thickness T is minimized.

The present embodiment is described by way of an example in which the second film 500 is formed on the first film 400 by performing the first cycle including the steps S11 through S14 under the high speed film-forming condition the first predetermined number of times and thereafter performing the second cycle including the steps S21 through S24 under the low speed film-forming condition the second predetermined number of times. However, the present embodiment is not limited thereto. For example, the first film 400 may be formed on the second film 500 by performing the second cycle including the steps S21 through S24 under the low speed film-forming condition the second predetermined number of times and thereafter performing the first cycle including the steps S11 through S14 under the high speed film-forming condition the first predetermined number of times.

For example, when the error between the first film 400 (which is formed by performing the first cycle including the steps S11 through S14 under the high speed film-forming condition the first predetermined number of times) and the target thickness T becomes small, the thickness of the first film 400 may be measured. Then, the low speed film-forming process may be performed by calculating the second predetermined number of times capable of minimizing the error from the target thickness T based on a result of measuring the thickness of the first film 400.

### Second Embodiment of Present Disclosure

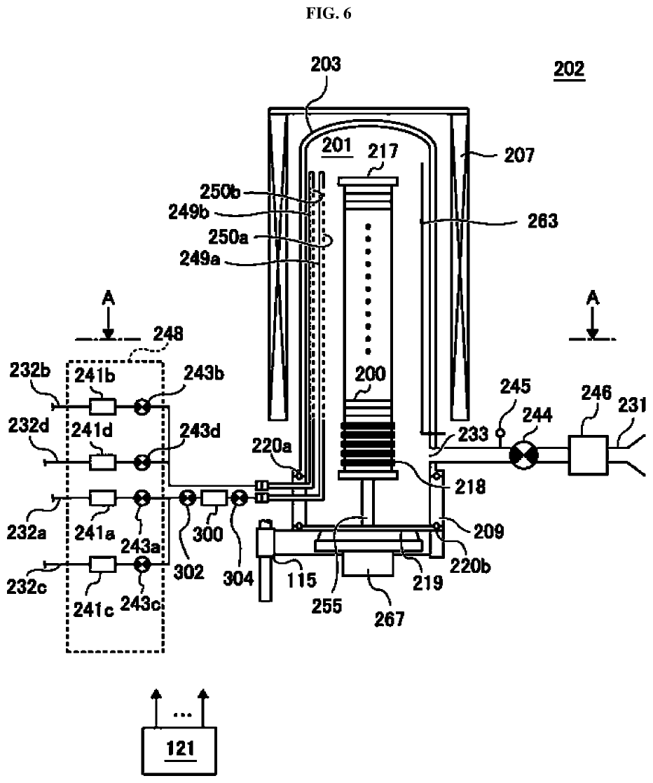

Subsequently, a substrate processing apparatus according to a second embodiment of the technique of the present disclosure will be described in detail with reference to FIG. 6. In the substrate processing apparatus according to the second embodiment, substantially the same components as those of the first embodiment described with reference to FIG. 1 will be denoted by like reference numerals, and detailed descriptions thereof will be omitted.

According to the second embodiment, as shown in FIG. 6, at a downstream side of the valve 243a of the gas supply pipe 232a serving as a part of the source gas supplier and at a downstream side of a confluence portion with the gas supply pipe 232c serving as a part of the inert gas supplier, a valve 302, a tank 300 serving as a reservoir in which the gas is stored and a valve 304 are sequentially installed in this order from an upstream side to a downstream side in the gas flow direction. That is, the tank 300 and the valves 302 and 304 are provided on a supply line through which the source gas and the inert gas are supplied.

By opening and closing the valve 302 at the upstream side in the gas flow direction and the valve 304 at the downstream side in the gas flow direction, the source gas supplied through the gas supply pipe 232a and the inert gas supplied through the gas supply pipe 232c are temporarily stored in the tank 300. The source gas and the inert gas are mixed in the tank 300. As a result, the source gas is diluted with the inert gas. Then, a large amount of the source gas stored in the tank 300 and diluted with an inert gas is supplied to the wafer 200 simultaneously (at once).

According to the second embodiment, in each of the source gas supply steps (that is, in the steps S11 and S21) of the substrate processing described above, a flash type supply is performed by using the tank 300 and the valves 302 and 304 at substantially the same process temperature.

Specifically, when the source gas is supplied in each of the steps S11 and S21, by closing the valve 304 in advance and opening the valves 243a, 243c and 302, the source gas and the inert gas whose flow rates are respectively adjusted by the MFCs 241a and 241c are stored in the tank 300. Then, by opening the valve 304, a large amount of a mixed gas of the source gas and the inert gas stored in the tank 300 is supplied to the wafer 200 at once. That is, a large amount of the source gas diluted in a manner described above is supplied to the wafer 200 at once.

In such a case, in the step S11 and the step S21, by respectively controlling the MFCs 241a and 241c and the valves 243a and 243c, it is possible to control the supply flow rate of the source gas and the supply flow rate of the inert gas. Thereby, it is possible to adjust the supply concentration of the source gas in the tank 300 (that is, the partial pressure of the source gas in the tank 300). That is, it is possible to adjust the ratio of the supply flow rate of the inert gas to the supply flow rate of the source gas in the step S11 described above and the ratio of the supply flow rate of the inert gas to the supply flow rate of the source gas in the step S21 described above.

For example, the source gas is stored in the tank 300 by adjusting the supply concentration of the source gas such that a flow rate ratio of the source gas to the inert gas in the step S21 is set to be smaller than the flow rate ratio of the source gas to the inert gas in the step S11. In other words, the ratio of the supply flow rate of the inert gas to the supply flow rate of the source gas in the step S21 is set to be greater than the ratio of the supply flow rate of the inert gas to the supply flow rate of the source gas in the step S11. As a result, it is possible to set the thickness of the third layer formed in the step S21 to be smaller than the thickness of the first layer formed in the step S11. That is, it is possible to set the cycle rate in the step S21 to be smaller than the cycle rate in the step S11. In such a case, the total flow rate of the source gas and the inert gas stored in advance in the tank 300 in the step S11 and the total flow rate of the source gas and the inert gas stored in advance in the tank 300 in the step S21 are set to be the same. By setting the total flow rate of the source gas and the inert gas in the step S21 the same as that in the step S11, it is possible to adjust the exposure amount of the source gas to the wafer 200 without changing the conditions such as the inner pressure of the process chamber 201.

According to the present embodiment, it is also possible to obtain substantially the same effects as in the first embodiment described above. Further, according to the present embodiment, by exposing the wafer 200 to the large amount of the source gas in a short time, it is also possible to improve a step coverage performance (also referred to as a “step coverage”).

### Other Embodiments of Present Disclosure

While the technique of the present disclosure is described in detail by way of the embodiments described above, the technique of the present disclosure is not limited thereto. The technique of the present disclosure may be modified in various ways without departing from the scope thereof.

For example, the embodiments described above are described by way of an example in which the nitrogen-containing gas is used as the reactive gas. However, the technique of the present disclosure is not limited thereto. For example, a gas containing oxygen (O) (that is, an oxygen-containing gas) may be used as the reactive gas. As the oxygen-containing gas, for example, a gas such as O2 gas, O3 gas), nitrous oxide (N2O) gas, nitrogen monoxide (NO) gas, nitrogen dioxide (NO2) gas, carbon monoxide (CO) gas and carbon dioxide (CO2) gas may be used. As the reactive gas, for example, one or more of the gases exemplified above as the oxygen-containing gas may be used.

For example, when the silicon-containing gas is used as the source gas and the oxygen-containing gas is used as the reactive gas, it is possible to form a silicon oxide film (also referred to as a “SiO film”). Even when forming the SiO film on the substrate, it is possible to obtain substantially the same effects as in the embodiments described above.

For example, even when the reactive gas excited into a plasma state is used as the reactive gas, it is possible to obtain substantially the same effects as in the embodiments described above. For example, the nitrogen-containing gas excited into the plasma state may be used as the reactive gas excited into the plasma state.

For example, the embodiments described above are described by way of an example in which the source gas and the reactive gas are supplied. However, the technique of the present disclosure is not limited thereto. For example, the technique of the present disclosure may also be applied when the film containing the predetermined element is formed on the wafer 200 by further supplying a modification gas capable of modifying the quality of the film in addition to the source gas and the reactive gas. Specifically, for example, by using the silicon-containing gas as the source gas, the nitrogen-containing gas as the reactive gas and a hydrogen-containing gas such as H2 gas as the modification gas, it is possible to form the SiN film on the substrate by a film-forming sequence of performing a cycle described below n times under the high speed film-forming condition when the source gas is supplied and performing a cycle described below m times under the low speed film-forming condition when the source gas is supplied. Even in such a case, it is possible to obtain substantially the same effects as in the embodiments described above.

(Si-containing Gas→H-containing Gas→N-containing Gas)×n→(Si-containing Gas→H-containing Gas→N-containing Gas)×m=>SiN

For example, by using the silicon-containing gas as the source gas, the oxygen-containing gas as the reactive gas and the hydrogen-containing gas as the modification gas, it is possible to form the SiO film on the substrate by a film-forming sequence of performing a cycle described below n times under the high speed film-forming condition when the source gas is supplied and performing a cycle described below m times under the low speed film-forming condition when the source gas is supplied. Even in such a case, it is possible to obtain substantially the same effects as in the embodiments described above.

(Si-containing Gas→H-containing Gas→O-containing Gas)×n→(Si-containing Gas→H-containing Gas→O-containing Gas)×m=>SiO

(Si-containing Gas→H-containing Gas+O-containing Gas)×n→(Si-containing Gas→H-containing Gas+O-containing Gas)×m=>SiO

For example, the embodiments described above are described by way of an example in which a film containing silicon is formed as the film containing the predetermined element. However, the technique of the present disclosure is not limited thereto. For example, the technique of the present disclosure may also be applied when a film containing a metal element is formed as the film containing the predetermined element. For example, as the film containing the metal element, a film such as a titanium nitride film (TiN film), a tungsten film (W film), a tungsten nitride film (WN film), a hafnium nitride film (HfN film), a zirconium nitride film (ZrN film), a tantalum nitride film (TaN film), a molybdenum film (Mo film), a molybdenum nitride film (MoN film), an aluminum film (Al film), an aluminum nitride film (AlN film), a ruthenium film (Ru film), a cobalt film (Co film) and a titanium film (Ti film) may be formed. Even in such a case, it is possible to obtain substantially the same effects as in the embodiments described above.

For example, the embodiments described above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of simultaneously processing one or several substrates at a time is used to form the film. For example, the embodiments described above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process sequences and the process conditions of each process using the substrate processing apparatuses exemplified above may be substantially the same as those of the embodiments described. Even in such a case, it is possible to obtain substantially the same effects as in the embodiments described above.

Further, the embodiments described above and modified examples described above may be appropriately combined. The process sequences and the process conditions of each combination thereof may be substantially the same as those of the embodiments described above.

### Example of Present Disclosure

By using the substrate processing apparatus described above, the substrate processing described above is performed to form the SiN film on the wafer 200. The chlorosilane-based gas exemplified above in the embodiments is used as the source gas, the hydrogen nitride-based gas exemplified above in the embodiments is used as the reactive gas, and the N₂ gas is used as the inert gas. The target thickness T of the film is set to 100 Å.

The cycle rate is 1.018 Å/cycle when a high speed film-forming process (that is, the first film forming step) is performed on the wafer 200 with an atmosphere of 100% of the source gas. On the other hand, the cycle rate is 0.76 Å/cycle when the low speed film-forming process (that is, the second film forming step) is performed on the wafer 200 with an atmosphere of 50% of the source gas and 50% of the inert gas. First, 96 executions of the first cycle including the steps S11 through S14 are performed under the high speed film-forming condition to form the SiN film with a thickness of 97.7 Å, which is about 95% of the target thickness T. Subsequently, three executions of the second cycle including the steps S21 through S24 are performed under the low speed film-forming condition to form the SiN film with a thickness of 2.3 Å. In other words, the total thickness is 100 Å. It is confirmed that, by performing the high speed film-forming process under the high speed film-forming condition and the low speed film-forming process under the low speed film-forming condition, it is possible to form the film whose thickness is not different from the target thickness T.

According to some embodiments of the present disclosure, it is possible to form the film with a desired thickness on the substrate.

What is claimed is:

1. A substrate processing method comprising:
forming a film containing a predetermined element and constituted by a first film and a second film on a substrate by performing:
(a) forming the first film containing the predetermined element by performing a first cycle a first predetermined number of times under a first condition, wherein the first cycle comprises:
(a-1) forming a first layer containing the predetermined element by supplying a source gas containing the predetermined element to the substrate; and
(a-2) modifying the first layer into a second layer containing the predetermined element by supplying a reactive gas reacting with the first layer to the substrate; and
(b) forming the second film containing the predetermined element by performing a second cycle a second predetermined number of times under a second condition different from the first condition, wherein the second cycle comprises:
(b-1) forming a third layer containing the predetermined element by supplying the source gas to the substrate; and
(b-2) modifying the third layer into a fourth layer containing the predetermined element by supplying the reactive gas to the substrate,
wherein the first condition and the second condition are set such that a thickness of the fourth layer formed in (b-2) is set to be smaller than a thickness of the second layer formed in (a-2).

2. The substrate processing method of claim 1, wherein a composition of the first film is equal to a composition of the second film.

3. The substrate processing method of claim 1, wherein (a) and (b) are performed under a same process temperature.

4. The substrate processing method of claim 1, wherein the first condition is a condition applied when supplying the source gas to the substrate in (a-1), the second condition is a condition applied when supplying the source gas to the substrate in (b-1), and
wherein the second condition is set such that a thickness of the third layer is set to be smaller than a thickness of the first layer.

5. The substrate processing method of claim 1, wherein the first condition comprises a supply flow rate of the source gas in (a-1) and the second condition comprises the supply flow rate of the source gas in (b-1), and
wherein the supply flow rate of the source gas in (b-1) is set to be smaller than the supply flow rate of the source gas in (a-1).

6. The substrate processing method of claim 1, wherein the first condition comprises a supply time of the source gas per cycle in (a-1) and the second condition comprises the supply time of the source gas per cycle in (b-1), and
wherein the supply time of the source gas per cycle in (b-1) is set to be shorter than the supply time of the source gas per cycle in (a-1).

7. The substrate processing method of claim 1, wherein the first condition comprises a supply concentration of the source gas in (a-1) and the second condition comprises the supply concentration of the source gas in (b-1), and
wherein the supply concentration of the source gas in (b-1) is set to be lower than the supply concentration of the source gas in (a-1).

8. The substrate processing method of claim 1, wherein an inert gas is supplied to the substrate in (a-1) and (b-1) during at least a part of a supply period of the source gas, and
wherein the first condition comprises a ratio of a supply flow rate of the inert gas to a supply flow rate of the source gas in (a-1) and the second condition comprises the ratio of the supply flow rate of the inert gas to the supply flow rate of the source gas in (b-1), and
wherein the ratio in (b-1) is set to be greater than the ratio in (a-1).

9. The substrate processing method of claim 1, wherein an inert gas is supplied to the substrate in (a-1) and (b-1) during at least a part of a supply period of the source gas, and
wherein the first condition comprises a supply flow rate of the inert gas in (a-1) and the second condition comprises the supply flow rate of the inert gas in (b-1), and
wherein the supply flow rate of the inert gas in (b-1) is set to be greater than the supply flow rate of the inert gas in (a-1).

10. The substrate processing method of claim 9, wherein the inert gas is supplied to the substrate through a supply port different from another supply port through which the source gas is supplied.

11. The substrate processing method of claim 9, wherein the inert gas is supplied to the substrate after being mixed with the source gas.

12. The substrate processing method of claim 9, wherein a tank and a valve arranged downstream of the tank are provided on a supply line through which the source gas and the inert gas are supplied, and
wherein, in each of (a-1) and (b-1), the source gas and the inert gas are stored in the tank by closing the valve, and the source gas and the inert gas stored in the tank are supplied to the substrate by opening the valve.

13. The substrate processing method of claim 12, wherein, by setting a flow rate ratio of the source gas to the inert gas in (b-1) to be smaller than the flow rate ratio of the source gas to the inert gas in (a-1), a thickness of the third layer formed in (b-1) is set to be smaller than a thickness of the first layer formed in (a-1).

14. The substrate processing method of claim 1, wherein a thickness of the second film formed in (b) is set to be smaller than a thickness of the first film formed in (a).

15. The substrate processing method of claim 1, wherein the first predetermined number of times is set to be greater than the second predetermined number of times.

16. The substrate processing method of claim 1, wherein (b) is performed after (a), and the second film is formed on the first film.

17. The substrate processing method of claim 1, wherein the first predetermined number of times and the second predetermined number of times are set such that a difference between a target thickness and a thickness of the film containing the predetermined element and constituted by the first film and the second film is set to be smaller than a minimum difference between the target thickness and a thickness obtained by multiplying the thickness of the second layer formed per cycle in (a-2) by a value n, and
wherein n is an arbitrary natural number.

18. A method of manufacturing a semiconductor device, comprising the substrate processing method of claim 1.

19. A non-transitory computer-readable recording medium storing a program that causes a substrate processing apparatus, by a computer, to perform:
forming a film containing a predetermined element and constituted by a first film and a second film on a substrate by performing:
(a) forming the first film containing the predetermined element by performing a first cycle a first predetermined number of times under a first condition, wherein the first cycle comprises:
(a-1) forming a first layer containing the predetermined element by supplying a source gas containing the predetermined element to the substrate; and
(a-2) modifying the first layer into a second layer containing the predetermined element by supplying a reactive gas reacting with the first layer to the substrate; and
(b) forming the second film containing the predetermined element by performing a second cycle a second predetermined number of times under a second condition different from the first condition, wherein the second cycle comprises:
(b-1) forming a third layer containing the predetermined element by supplying the source gas to the substrate; and
(b-2) modifying the third layer into a fourth layer containing the predetermined element by supplying the reactive gas to the substrate,
wherein the first condition and the second condition are set such that a thickness of the fourth layer formed in (b-2) is set to be smaller than a thickness of the second layer formed in (a-2).

20. A substrate processing apparatus comprising:
a source gas supplier through which a source gas containing a predetermined element is supplied to a substrate;
a reactive gas supplier through which a reactive gas is supplied to the substrate; and
a controller configured to be capable of controlling the source gas supplier and the reactive gas supplier to perform:
forming a film containing the predetermined element and constituted by a first film and a second film on the substrate by performing:
(a) forming the first film containing the predetermined element by performing a first cycle a first predetermined number of times under a first condition, wherein the first cycle comprises:
(a-1) forming a first layer containing the predetermined element by supplying the source gas to the substrate; and
(a-2) modifying the first layer into a second layer containing the predetermined element by supplying the reactive gas to the substrate; and
(b) forming the second film containing the predetermined element by performing a second cycle a second predetermined number of times under a second condition different from the first condition, wherein the second cycle comprises:
(b-1) forming a third layer containing the predetermined element by supplying the source gas to the substrate; and
(b-2) modifying the third layer into a fourth layer containing the predetermined element by supplying the reactive gas to the substrate,
wherein the first condition and the second condition are set such that a thickness of the fourth layer formed in (b-2) is set to be smaller than a thickness of the second layer formed in (a-2).
